(19) United States
(12) Patent Application Publication
(10) Pub. No.: US 2024/0194561 A1
(43) Pub. Date: Jun. 13, 2024

(54) HETERO-JUNCTION BIPOLAR TRANSISTOR AND METHOD OF MANUFACTURING THE SAME

(71) Applicant: Nippon Telegraph and Telephone Corporation, Tokyo (JP)

(72) Inventor: Yuta Shiratori, Tokyo (JP)

(21) Appl. No.: 18/554,309

(22) PCT Filed: May 12, 2021
(86) PCT No.: PCT/JP2021/018000

§ 371 Date: Oct. 6, 2023

(51) Int. Cl. H01L 23/373; H01L 21/48; H01L 21/78; H01L 29/205; H01L 29/66; H01L 29/737

(52) U.S. Cl. CPC H01L 23/373; H01L 21/4803; H01L 21/7806; H01L 29/205; H01L 29/66318; H01L 29/7371

(57) ABSTRACT

A hetero-junction bipolar transistor includes a heat dissipation structure made of metal, having one end in contact with top of a heat dissipation substrate around an element part and formed to penetrate a protective layer, and includes a collector wiring formed on the protective layer in contact with top of the heat dissipation structure and a collector electrode, a base contact electrode connected to the base electrode and penetrating the protective layer, and a base wiring connected to the base contact electrode and formed on the protective layer.

### CROSS-REFERENCE TO RELATED APPLICATIONS

This application is a national phase entry of PCT Application No. PCT/JP2021/018000, filed on May 12, 2021, which application is hereby incorporated herein by reference.

### TECHNICAL FIELD

The present invention relates to a hetero-junction bipolar transistor and a manufacturing method thereof.

### BACKGROUND

An indium-phosphorus (InP)-based hetero-junction bipolar transistor (HBT) is a transistor with excellent high-speed and high-power characteristics that is suitable for integrated circuits for optical/wireless communication. In order to achieve a further increase in speed of the InP-based HBT, it is important to reduce a capacitance and shorten an electron traveling time by miniaturizing an element, while maintaining an operating current amount. In addition, in increasing the high-power characteristic, it is required to increase the number of emitters in a so-called multi-finger structure in which a plurality of emitters is integrated in a manner sharing a base or a collector and to reduce an interval between emitters.

On the other hand, since a thermal resistance of an element increases due to the miniaturization, a junction temperature of the element (an internal temperature of the element) increases due to the miniaturization. In addition, in the multi-finger structure, due to a heat generation of an emitter region disposed at an outer peripheral portion, a heat dissipation of the emitter region disposed at a center is hindered as compared with the HBT of a single finger, so that the junction temperature is further increased.

Since the junction temperature is a factor that greatly affects not only direct electrical characteristics such as current gain and high-frequency characteristics but also long-term reliability, heat dissipation measures are essential when increasing the HBT speed.

In order to improve the heat dissipation property of the HBT, a technique for forming an HBT structure on a support substrate having a high thermal conductivity, for example, has been proposed (NPL 1).

In the HBT structure in NPL 1, as shown in FIG. 3, a collector electrode layer 302 made of metal is formed on a heat dissipation substrate 301, a collector contact layer 303 made of a crystal of a compound semiconductor, a collector layer 304, a base layer 305, and an emitter layer 306 are formed on the collector electrode layer 302. Further, a base electrode 307 is formed on the base layer 305, and an emitter electrode 308 is formed on the emitter layer 306.

This HBT structure is obtained by epitaxially growing each layer constituting the HBT on an InP growth substrate, then bonding the layer to the heat dissipation substrate 301 via the collector electrode layer 302, removing the unnecessary InP growth substrate, and processing each layer so as to form the HBT structure.

Generally, heat generated in the HBT is generally dissipated toward the substrate by heat conduction in a solid body. According to the above structure, because the layer under the collector contact layer 303 is made of a material having a higher thermal conductivity than a compound semiconductor constituting the emitter layer 306, the base layer 305, the collector layer 304, and the collector contact layer 303, the heat dissipation property of the HBT can be improved.

On the other hand, unlike a case where an HBT structure is formed on a typical InP substrate, a step of bonding the HBT structure to the heat dissipation substrate is required, and therefore, there is a concern that various problems may occur in various manufacturing methods as described later.

First, as shown in NPL 1, in order to realize the above-mentioned HBT structure on the heat dissipation substrate by one substrate bonding process, unlike the case where the HBT structure is formed on an ordinary InP substrate, an HBT crystal layer needs to be epitaxially grown in a reverse order (an order of the emitter layer, the base layer, and the collector layer from the side in contact with the InP substrate).

Usually, in epitaxial growth, an optimum temperature profile is set in consideration of the deterioration of the semiconductor crystal quality of the lower layer and the unintended thermal diffusion of constituent elements so as to obtain the best crystal quality of various materials. On the other hand, when the HBT crystal layer is epitaxially grown from the emitter layer side, the semiconductor materials of the lower layer and the upper layer are replaced with each other, so that the case where it is difficult to set the optimum temperature profile occurs.

In addition, InGaAs having a high In composition is often used for the outermost layer (layer in direct contact with the emitter electrode) of the emitter layer in order to reduce the contact resistance of the emitter. Since InGaAs having the high In composition is not lattice-matched with InP, it is generally difficult to form a high-quality crystal. However, since InGaAs having the high In composition is the outermost layer, it is not necessary to consider the crystal quality of the upper semiconductor material, and in addition, by controlling the thickness of the upper semiconductor material to be equal to or less than the critical film thickness, lattice relaxation is suppressed, thereby achieving the crystal quality capable of obtaining sufficient electrical characteristics.

However, when grown from the side of the emitter layer, the emitter layer, the base layer, and the collector layer to be lattice-unmatched are formed on InGaAs having the high In composition. Therefore, the crystal quality of the HBT crystal layer is deteriorated, or it is feared that it becomes difficult to introduce InGaAs having the high In composition into the emitter layer.

From the above, when the structure of the above-mentioned NPL 1 is realized by one substrate bonding process, there is a concern that the crystal quality of the HBT crystal layer is deteriorated or the composition is restricted.

The simplest method for solving the above problem is to carry out the substrate bonding process twice. First, after an HBT crystal growth layer is epitaxially grown, it is bonded to the support substrate by using some temporary adhesive layer, and the InP substrate is removed. In this case, the HBT crystal layers are formed on the support substrate in a state in which the order of the HBT crystal layers is reversed. Next, the HBT crystal layer on the support substrate and the heat dissipation substrate are bonded via a metal layer in the same manner as in NPL 1, and the unnecessary temporary adhesive layer and the support substrate are removed. Since the HBT crystal layer is transferred twice at this stage, the HBT crystal layer is formed on the heat dissipation substrate in the order of growth on the InP substrate. Finally, the HBT structure is produced by a known method, whereby the structure of NPL 1 can be obtained.

In this case, since the HBT crystal layer can be grown on the InP growth substrate in the normal order (in the order from the collector layer to the emitter layer), the crystal quality does not deteriorate in the epitaxial growth process. However, the substrate bonding process is simply required twice, so that not only is the process complicated but also there is a concern that the quality of the HBT crystal layer may be deteriorated in some cases.

In general, when some particle or local unevenness is generated on the surface to be bonded, it also depends on the physical properties of the material to be bonded, but there is a possibility that an unbonded region having 100 to 1,000 times or more of the size of the material to be bonded may be generated. Accordingly, as the number of bonding processes increases, the risk of occurrence of an unintended unbonded region increases, which may result in a potential reduction in yield.

Further, in the second bonding, bonding pressure is applied to the HBT crystal layer which is a thin layer (thickness of 1 μm or less) and extremely mechanically fragile and bonds the HBT crystal layer to the heat dissipation substrate. Although the HBT crystal layer is held on the support substrate by the temporary adhesive layer, there is a concern that the crystal quality is deteriorated and cracks are generated in the worst case due to the influence of minute deformation of the temporary adhesive layer due to the bonding pressure. Therefore, as an ideal temporary adhesive layer, a material easy to peel and hard to deform (high Young's modulus) is preferable, however, the high Young's modulus is a trade-off with bonding easiness, and it is not easy to select a temporary adhesive layer which satisfies all requirements in a well-balanced manner.

In order to avoid the above problem, a technique has been proposed for forming the HBT structure by a collector-up process with a single substrate bonding without changing the epitaxial growth order (NPL 2).

For example, as shown in FIG. 4, a bonding layer 402 made of benzocyclobutene (BCB) is formed on a heat dissipation substrate 401, and an HBT element part is formed on this layer in an order of a first emitter electrode 403, a second emitter electrode 404, an emitter layer 405, a base layer 406, a collector layer 407, a sub-collector layer 408, and a collector electrode 409.

Further, a thermal via 410 made of Au in contact with the heat dissipation substrate 401 is formed on the extension of the emitter layer 405 in a transverse direction, and is connected to the first emitter electrode 403. Furthermore, the element part and the thermal via 410 are covered with a protective layer 411 made of BCB.

In this structure, the HBT element part including the first emitter electrode 403, the second emitter electrode 404, the emitter layer 405, the base layer 406, the collector layer 407, and the sub-collector layer 408 is formed on the InP substrate, and then is bonded to the heat dissipation substrate via the bonding layer 402.

After this bonding, the unnecessary InP growth substrate is removed to form a collector electrode 409 in the sub-collector layer 408. Finally, an opening is formed in the bonding layer 402 at the outer peripheral portion of the element part, the thermal via 410 is formed so as to be in contact with the heat dissipation substrate 401 and the first emitter electrode 403, and then the whole element part is covered with the protective layer 411.

By constituting the adhesive layer (bonding layer) of BCB having a low Young's modulus, the bonding layer can be bonded to the heat dissipation substrate under a relatively low bonding pressure condition as compared with a case where a metal is used for a material to be bonded, thereby avoiding a destruction of the HBT element part whose mechanical strength is fragile. In addition, in this structure, heat generated in the element part is dissipated toward the heat dissipation substrate through the Au thermal via, so that a higher heat dissipation property can be obtained as compared with the HBT structure on the InP substrate.

### CITATION LIST

### Non Patent Literature

NPL 1 Y. Shiratori et al., “High-Speed InP/InGaAsSb DHBT on High-Thermal-Conductivity SiC Substrate”, IEEE Electron Device Letters, vol. 39, No. 6, pp. 807-810, 2018.
NPL 2 T. Kraemer et al., “InP DHBT Process in Transferred-Substrate Technology With ft and fmax Over 400 GHz”, IEEE Transactions on Electron Devices, vol. 56, No. 9, pp. 1897-1903, 2009.

### SUMMARY

### Technical Problem

However, in the structure of NPL 2, since BCB having extremely low thermal conductivity exists just under the element part, the path from the emitter layer to the heat dissipation substrate is made to be long due to the length of the emitter electrode and the thickness of the Au thermal via. Therefore, compared with NPL 1 in which all portions immediately below the element part are made of a high thermal conductivity material, the effect of improving the heat dissipation property is limited.

Further, since the Au thermal via having a constant size is required for the heat dissipation between the HBT element part and the element part, when the multi-finger structure in which a plurality of emitters is disposed in parallel at a high density is formed, the emitter interval is restricted. This may be a serious problem particularly in increasing the high power of the HBT.

As described above, the existing technique has a problem that it is not easy to improve the heat dissipation property while suppressing the deterioration of the crystal quality and the deterioration of the integration density of the InP-based HBT.

Embodiments of the present invention were achieved in order to solve the foregoing problem, and an object of embodiments of the present invention is to further improve the heat dissipation property while suppressing the deterioration of the crystal quality and the deterioration of the integration density of the InP-based HBT.

### Solution to Problem

A hetero-junction bipolar transistor according to embodiments of the present invention includes a heat dissipation substrate made of an insulating material having a thermal conductivity higher than that of InP, a first emitter electrode formed on the heat dissipation substrate, a second emitter electrode formed on the first emitter electrode with an area smaller than that of the first emitter electrode, an emitter layer made of a compound semiconductor and formed on the second emitter electrode, a base layer made of a compound semiconductor and formed on the emitter layer, a collector layer made of a compound semiconductor and formed on the base layer, a collector contact layer made of a compound semiconductor and formed on the collector layer, a collector electrode formed on the collector contact layer, a base electrode formed to be connected to the base layer, a protective layer formed on the heat dissipation substrate so as to cover a side of an element part constituted by the second emitter electrode, the emitter layer, the base layer, the collector layer, and the collector contact layer, the first emitter electrode, and the base electrode, an emitter contact electrode formed in contact with the top of the first emitter electrode around the element part and penetrating the protective layer, an emitter wiring connected to the emitter contact electrode and formed on the protective layer, a heat dissipation structure made of a metal having one end in contact with the top of the heat dissipation substrate around the element part and formed through the protective layer, a collector wiring formed on the protective layer in contact with the top of the heat dissipation structure and the collector electrode, a base contact electrode connected to the base electrode and penetrating the protective layer, and a base wiring connected to the base contact electrode and formed on the protective layer.

An manufacturing method of a hetero-junction bipolar transistor according to embodiments of the present invention is a manufacturing method for manufacturing the above mentioned hetero-junction bipolar transistor and includes a first process of performing crystal growth of an etch stop layer, a collector contact forming layer, a collector forming layer, a base forming layer, and an emitter forming layer in this order which are made of a compound semiconductor on a growth substrate made of InP, a second process of forming an element part by forming a second emitter electrode on the emitter forming layer, processing the emitter forming layer, the base forming layer, and the collector forming layer, forming the emitter layer, the base layer, and the collector layer, and forming the base electrode on the base layer around the emitter layer, a third process of forming a first structure body made of a metal on the growth substrate around the element part, a fourth process of filling a periphery of the element part and forming a first protective layer in which one end side of the first structure body and the second emitter electrode are exposed and a surface is flattened, a fifth process of forming a first adhesive metal layer on the flattened first protective layer, a sixth process of preparing a heat dissipation substrate made of an insulating material having higher thermal conductivity than that of InP and in which a second adhesive metal layer is formed on the surface, a seventh process of bringing the first adhesive metal layer of the growth substrate and the second adhesive metal layer of the heat dissipation substrate into contact with each other so as to face each other, forming an adhesive metal layer in which the first adhesive metal layer and the second adhesive metal layer are integrated, and laminating the growth substrate and the heat dissipation substrate, an eighth process of removing the growth substrate and the etch stop layer, bringing the element part into a state of being formed on the heat dissipation substrate in a state where the second emitter electrode is disposed on a side of the heat dissipation substrate, and exposing the collector contact forming layer, a ninth process of forming a collector electrode on the collector contact forming layer, a tenth process of forming a collector contact layer by processing the collector contact forming layer, and further removing a part of the collector layer and the base layer, and forming a contact hole reaching a part of the base electrode, an eleventh process of forming a first emitter contact electrode constituting a part of the emitter contact electrode and a first heat dissipation structure made of a metal and constituting a part of the heat dissipation structure, and forming the base contact electrode on the first structure body, a twelfth process of forming an emitter contact layer by processing the first structure body and forming a second emitter contact electrode connecting to the first emitter contact electrode, forming a second heat dissipation structure constituting a part of the heat dissipation structure and connected to the first heat dissipation structure, forming the first emitter electrode by processing the adhesive metal layer, and forming a third heat dissipation structure connected to the second heat dissipation structure to form the heat dissipation structure constituted by the first heat dissipation structure, the second heat dissipation structure, and the third heat dissipation structure, a thirteenth process of forming a second protective layer on the first protective layer to form a protective layer constituted by the first protective layer and the second protective layer, and a fourteenth process of forming an emitter wiring, a base wiring, and a collector wiring.

### Advantageous Effects of Embodiments of the Invention

As described above, according to embodiments of the present invention, since the protective layer covering the element part or the like is formed on the heat dissipation substrate, and the heat dissipation structure is provided which is made of metal and has one end in contact with a top of the heat dissipation substrate around the element part so as to penetrate the protective layer, it is possible to suppress the deterioration of the crystal quality and the deterioration of the integration density of the InP-based HBT to improve the heat dissipation property.

### BRIEF DESCRIPTION OF THE DRAWINGS

FIG. 1A is a cross-sectional view showing a configuration of a hetero-junction bipolar transistor according to an embodiment of the present invention.

FIG. 1B is a cross-sectional view showing a configuration of the hetero-junction bipolar transistor according to an embodiment of the present invention.

FIG. 2A is a cross-sectional view of a state of the hetero-junction bipolar transistor of a middle process for explaining a manufacturing method of the hetero-junction bipolar transistor according to an embodiment of the present invention.

FIG. 2B is a cross-sectional view of a state of the hetero-junction bipolar transistor of the middle process for explaining the manufacturing method of the hetero-junction bipolar transistor according to an embodiment of the present invention.

FIG. 2C is a cross-sectional view of a state of the hetero-junction bipolar transistor of the middle process for explaining the manufacturing method of the hetero-junction bipolar transistor according to an embodiment of the present invention.

FIG. 2D is a cross-sectional view of a state of the hetero-junction bipolar transistor of the middle process for explaining the manufacturing method of the hetero-junction bipolar transistor according to an embodiment of the present invention.

FIG. 2E is a cross-sectional view of a state of the hetero-junction bipolar transistor of the middle process for explaining the manufacturing method of the hetero-junction bipolar transistor according to an embodiment of the present invention.

FIG. 2F is a cross-sectional view of a state of the hetero-junction bipolar transistor of the middle process for explaining the manufacturing method of the hetero-junction bipolar transistor according to an embodiment of the present invention.

FIG. 2G is a cross-sectional view of a state of the hetero-junction bipolar transistor of the middle process for explaining the manufacturing method of the hetero-junction bipolar transistor according to an embodiment of the present invention.

FIG. 2H is a cross-sectional view of a state of the hetero-junction bipolar transistor of the middle process for explaining the manufacturing method of the hetero-junction bipolar transistor according to an embodiment of the present invention.

FIG. 2I is a cross-sectional view of a state of the hetero-junction bipolar transistor of the middle process for explaining the manufacturing method of the hetero-junction bipolar transistor according to an embodiment of the present invention.

FIG. 2J is a cross-sectional view of a state of the hetero-junction bipolar transistor of the middle process for explaining the manufacturing method of the hetero-junction bipolar transistor according to an embodiment of the present invention.

FIG. 2K is a cross-sectional view of a state of the hetero-junction bipolar transistor of the middle process for explaining the manufacturing method of the hetero-junction bipolar transistor according to an embodiment of the present invention.

FIG. 2L is a cross-sectional view of a state of the hetero-junction bipolar transistor of the middle process for explaining the manufacturing method of the hetero-junction bipolar transistor according to an embodiment of the present invention.

FIG. 2M is a cross-sectional view of a state of the hetero-junction bipolar transistor of the middle process for explaining the manufacturing method of the hetero-junction bipolar transistor according to an embodiment of the present invention.

FIG. 2N is a cross-sectional view of a state of the hetero-junction bipolar transistor of the middle process for explaining the manufacturing method of the hetero-junction bipolar transistor according to an embodiment of the present invention.

FIG. 2O is a cross-sectional view of a state of the hetero-junction bipolar transistor of the middle process for explaining the manufacturing method of the hetero-junction bipolar transistor according to an embodiment of the present invention.

FIG. 2P is a cross-sectional view of a state of the hetero-junction bipolar transistor of the middle process for explaining the manufacturing method of the hetero-junction bipolar transistor according to an embodiment of the present invention.

FIG. 2Q is a cross-sectional view of a state of the hetero-junction bipolar transistor of the middle process for explaining the manufacturing method of the hetero-junction bipolar transistor according to an embodiment of the present invention.

FIG. 2R is a cross-sectional view of a state of the hetero-junction bipolar transistor of the middle process for explaining the manufacturing method of the hetero-junction bipolar transistor according to an embodiment of the present invention.

FIG. 2S is a cross-sectional view of a state of the hetero-junction bipolar transistor of the middle process for explaining the manufacturing method of the hetero-junction bipolar transistor according to an embodiment of the present invention.

FIG. 2T is a cross-sectional view of a state of the hetero-junction bipolar transistor of the middle process for explaining the manufacturing method of the hetero-junction bipolar transistor according to an embodiment of the present invention.

FIG. 3 is a cross-sectional view showing a configuration of a HBT structure shown in NPL 1.

FIG. 4 is a cross-sectional view showing a configuration of the HBT structure shown in NPL 2.

### DETAILED DESCRIPTION OF ILLUSTRATIVE EMBODIMENTS

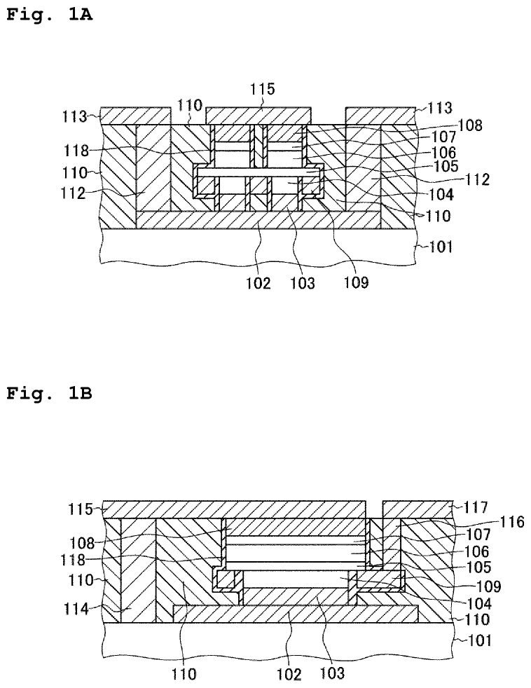

Hereinafter, a hetero-junction bipolar transistor according to an embodiment of the present invention will be described with reference to FIGS. 1A and 1B.

The hetero-junction bipolar transistor includes a heat dissipation substrate 101 made of an insulating material having a thermal conductivity higher than that of InP, a first emitter electrode 102 formed on the heat dissipation substrate 101, and a second emitter electrode 103 formed on the first emitter electrode 102 with an area smaller than that of the first emitter electrode 102.

In addition, this hetero-junction bipolar transistor includes an emitter layer 104 formed on the second emitter electrode 103, a base layer 105 formed on the emitter layer 104, a collector layer 106 formed on the base layer 105, and a collector contact layer 107 formed on the collector layer 106. These layers (crystal layers) are made of a compound semiconductor (for example, a group III-V compound semiconductor).

In addition, this hetero-junction bipolar transistor includes a collector electrode 108 formed on a collector contact layer 107, and a base electrode 109 formed so as to be connected to the base layer 105. Further, this hetero-junction bipolar transistor includes a protective layer 110 formed on the heat dissipation substrate 101 so as to cover the side of the element part, the first emitter electrode 102, and the base electrode 109. The element part is a part including the second emitter electrode 103, the emitter layer 104, the base layer 105, the collector layer 106, and the collector contact layer 107.

In addition, this hetero-junction bipolar transistor is formed on the first emitter electrode 102 around the element part and includes an emitter contact electrode 112 penetrating the protective layer 110, and an emitter wiring 113 connected to the emitter contact electrode 112 and formed on the protective layer 110.

In addition, this hetero-junction bipolar transistor includes a heat dissipation structure 114 made of metal whose one end is in contact with the heat dissipation substrate 101 around the element part, and which is formed so as to penetrate the protective layer 11o. The heat dissipation structure 114 is formed in the shape of a pillar.

Also, this hetero-junction bipolar transistor includes a collector wiring 115 formed on the protective layer 110 in contact with the heat dissipation structure 114 and the collector electrode 108, a base contact electrode 116 connected to the base electrode 109 and penetrating the protective layer 110, and a base wiring 117 connected to the base contact electrode 116 and formed on the protective layer 110.

Further, this hetero-junction bipolar transistor is made of an insulating material having a thermal conductivity higher than that of the collector layer 106 and the emitter layer 104, and includes an insulating layer 118 formed on the peripheral surface of the element part.

Here, in this example, a plurality of element parts is provided on the first emitter electrode 102, each of the plurality of element parts is formed in a rectangular shape in a plan view, and the plurality of rectangular cells is disposed in the direction of short sides (short sides) of the rectangular cells. This is a so-called multi-finger structure. In the embodiment, a plurality of emitter layers 104 (second emitter electrodes 103) and collector layers 106 (collector contact layers 107 and collector electrodes 108) are provided. Note that FIG. 1A shows a cross section in a direction parallel to the short side of the element part formed into the rectangular shape in a plan view, and FIG. 1B shows a cross section in a direction parallel to the long side (long side) of the element part formed into the rectangular shape in a plan view. In the case of the multi-finger structure, an emitter is divided, but in addition, a collector is also divided, so that an increase in parasitic capacitance can be suppressed, and this is advantageous in terms of high-frequency characteristics.

In addition, in the plurality of element parts, the collector layer 106 is formed to have an area larger than that of the emitter layer 104. Further, in each element part, the collector layer 106 and the emitter layer 104 are in a state where their centers overlap each other in a plan view. In the process of the current flowing from the emitter layer 104 to the collector layer 106, the current spreads after exiting the emitter layer 104, so that the collector layer 106 is formed to have a larger area.

According to the embodiment, heat generated in the element part is dissipated to the heat dissipation substrate 101 via the second emitter electrode 103 and the first emitter electrode 102. In addition, heat is dissipated to the heat dissipation substrate 101 from the collector layer 106 side via the collector electrode 108 made of a metal having high thermal conductivity, the collector wiring 115, and the heat dissipation structure 114. As a result, according to the embodiment, the heat dissipation property of the heat generated in the element part can be improved as compared with the conventional structure.

Further, as will be described later, since the layers of the respective crystals constituting the element part are formed by epitaxial growth in the same order of lamination as that of the conventional hetero-junction bipolar transistor, the deterioration of the crystal quality can be avoided.

In addition, the junction process necessary for manufacturing the hetero-junction bipolar transistor according to the embodiment in which the element part (the second emitter electrode 103, the emitter layer 104, the base layer 105, the collector layer 106, the layer to be used as the collector contact layer 107, and the base electrode 109) is formed, and then is bonded to the heat dissipation substrate only once. Therefore, as compared with the case where substrate bonding is performed twice, the deterioration of the crystal quality and the yield caused by the bonding process can be suppressed.

Further, as will be described later, in the manufacture of the hetero-junction bipolar transistor according to the embodiment, the element part and the heat dissipation substrate are bonded via an adhesive metal layer made of Au or Cu having a high thermal conductivity. In this case, a relatively high bonding pressure is required because of its high Young's modulus compared to the case of bonding by a resin layer such as benzocyclobutene (BCB). However, according to the embodiment, since a metal structure for constituting the emitter contact electrode 112 and the heat dissipation structure 114 is formed around the element part, local concentration of a bonding load to a crystal layer constituting the element part through the second emitter electrode 103 is suppressed, thus, they can be prevented from being destroyed in the bonding process.

Further, in the hetero-junction bipolar transistor according to the embodiment, since heat can be dissipated from the first emitter electrode 102 toward the heat dissipation substrate 101 immediately below, there is no need to diffuse the heat in the emitter short direction as in the case of NPL 2. Accordingly, according to the embodiment, as long as the accuracy of the processing technique allows, the emitter layer 104 and the second emitter electrode 103 are disposed in parallel with each other at high density without sacrificing the heat dissipation property, and a so-called multi-finger structure can be formed. Thus, the hetero-junction bipolar transistor which achieves both high heat dissipation property and high-power performance can be obtained.

Further, since the hetero-junction bipolar transistor according to the embodiment has a collector-up structure, only the area of the collector layer 106 can be relatively easily processed to be selectively smaller than that of the base layer 105. Thus, since collector parasitic capacitance can be reduced without reducing the contact area between the base electrode 109 and the base layer 105 (without increasing the base contact resistance), high-frequency characteristics can be improved.

As described above, according to the present embodiment, it is possible to improve the heat dissipation property by suppressing the deterioration of the crystal quality and the deterioration of the integration density of the InP-based HBT. Further, according to the embodiment, the HBT having the multi-finger structure with the high heat dissipation property can be formed by one bonding process, and an excellent effect can be obtained in which high speed and high-power performance can be improved and long-term reliability can be improved.

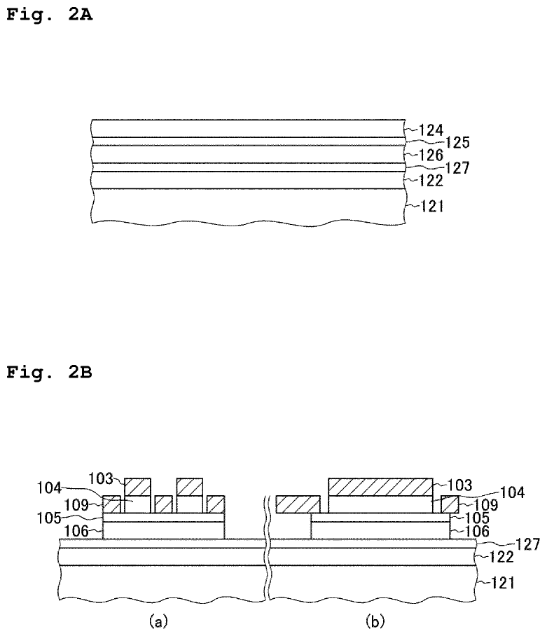

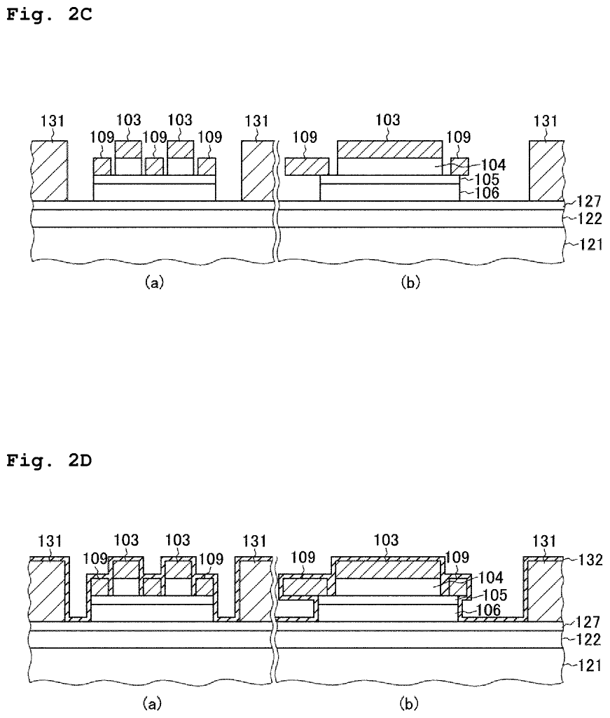

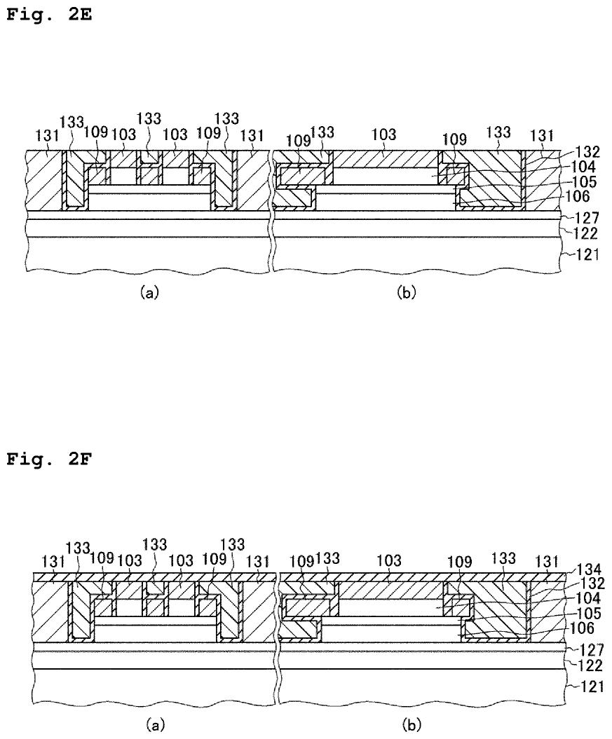

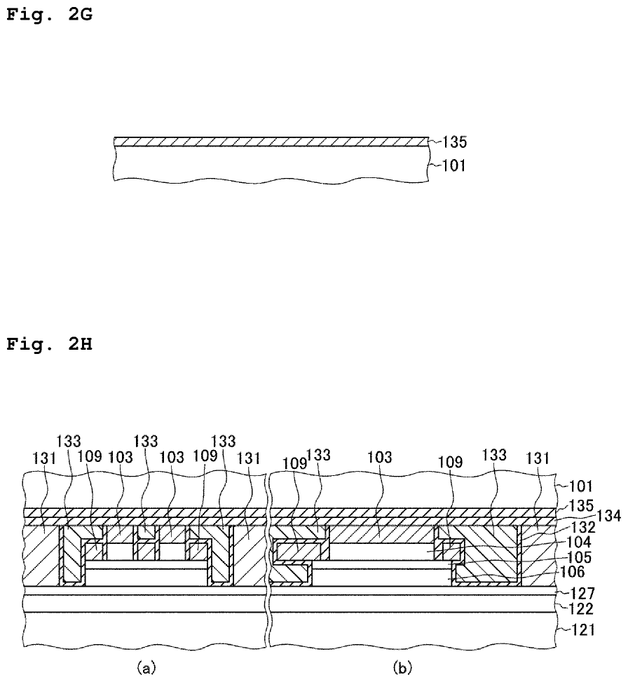

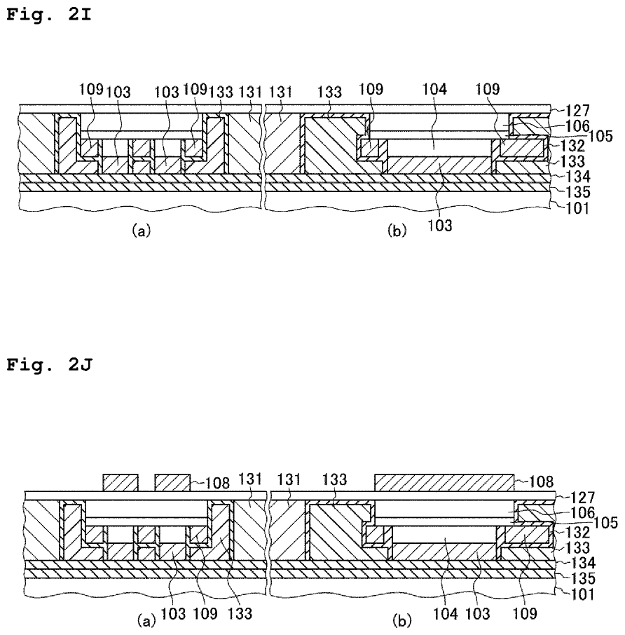

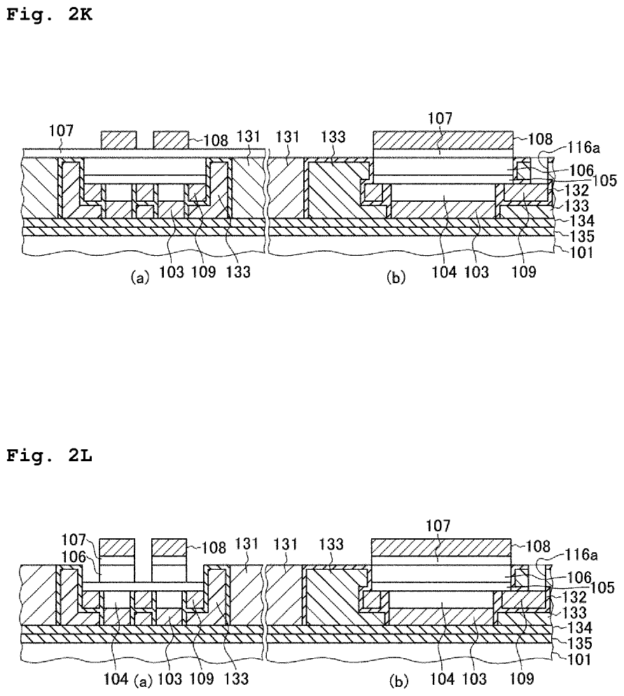

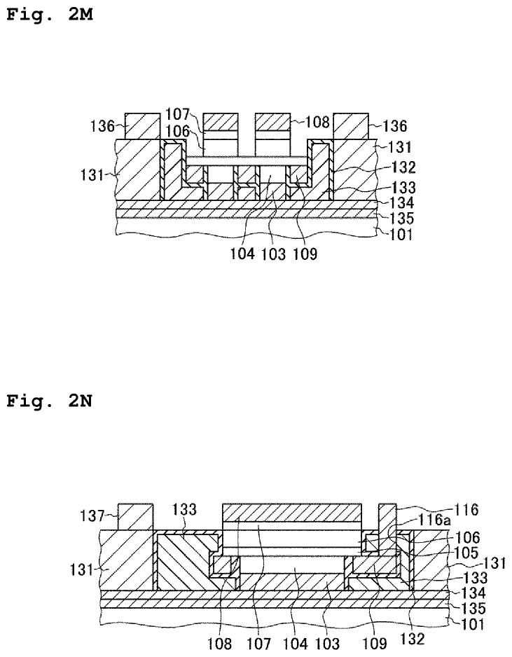

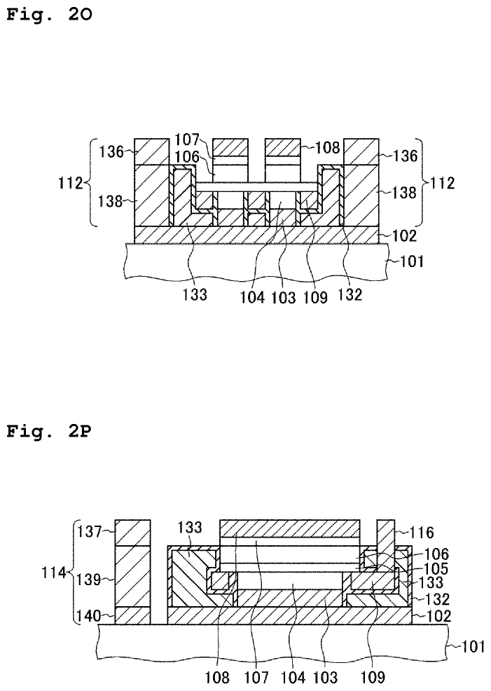

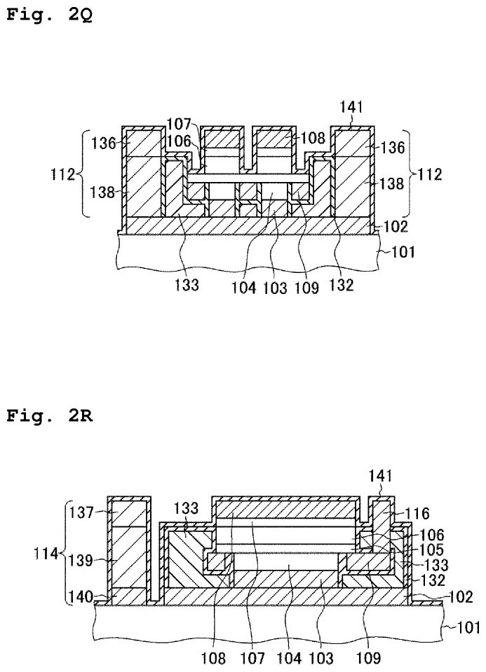

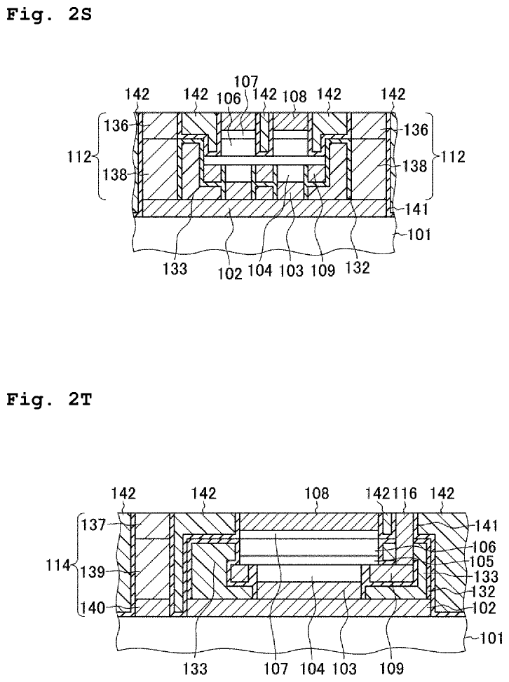

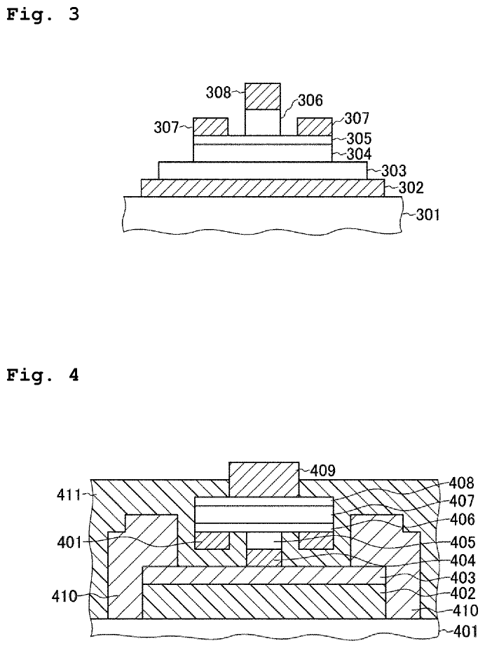

Next, a manufacturing method of the hetero-junction bipolar transistor according to an embodiment of the present invention will be described with reference to FIGS. 2A to 2T. This manufacturing method is a manufacturing method for manufacturing the above-mentioned hetero-junction bipolar transistor. In FIGS. 2A to 2F and FIGS. 2H to 2L, (a) shows a cross section in a direction parallel to a short side of the element part formed into a rectangular shape in a plan view, and (b) shows a cross section in a direction parallel to a long side of the element part formed into the rectangular shape in a plan view.

First, as shown in FIG. 2A, an etch stop layer 122, a collector contact forming layer 127, a collector forming layer 126, a base forming layer 125, and an emitter forming layer 124 which are respectively made of a compound semiconductor are formed on a growth substrate 121 made of InP by a crystal growth in this order (first process).

For example, the etch stop layer 122 can be formed of a laminated structure of a non-doped InGaAs layer and a non-doped InP layer. The collector contact forming layer 127 can be made of n-type InGaAs doped with Si at a high concentration. The collector forming layer 126 can be made of n-type InP doped with Si at a low concentration. The base forming layer 125 can be made of P-type GaAsSb doped with C at a high concentration. The emitter forming layer 124 can be made of n-type InP doped with Si at a low concentration.

Each layer of the group III-V compound semiconductor described above can be formed by crystal (epitaxial) growth using, for example, an organic metal vapor deposition method or a molecular beam epitaxy method. Since each of the above-mentioned crystal layers can be epitaxially grown on the growth substrate 121 made of InP in a lattice-matched state, good crystallinity with less transformation and defects can be obtained. Further, although not shown, by forming an emitter cap forming layer of InGaAs of a high In composition having a thickness equal to or less than a critical film thickness on the emitter forming layer 124, it is possible to reduce the contact resistance with the emitter electrode.

Next, as shown in FIG. 2B, a second emitter electrode 103 is formed on the emitter forming layer 124. Further, the emitter forming layer 124, the base forming layer 125, and the collector forming layer 126 are processed to form an emitter layer 104, a base layer 105, and a collector layer 106. In addition, a base electrode 109 is formed on the base layer 105 around the emitter layer 104. Thus, an element part is formed (second step).

Note that the parallel number of the second emitter electrodes 103 and the emitter layers 104 can be appropriately selected in accordance with the amount of output current required in the integrated circuit. The respective layers and the electrodes can be formed by using well-known semiconductor patterning techniques, film forming and etching techniques, and the like. The base electrode 109 forms a portion which becomes a so-called base pad electrode in one of the emitter longitudinal directions and whose width is wider than that of the other. This is used to facilitate the connection with the base wiring, as will be described later.

Next, as shown in FIG. 2C, a first structure body 131 made of a metal is formed on the growth substrate 121 around the above-mentioned element part (third process). The first structure body 131 is formed in a region excluding the element part and the outer periphery of the element part. The first structure body 131 is used as a layer for dispersing pressure in bonding. Further, since the first structure body 131 constitutes a part of a heat dissipation structure to be a heat dissipation path later, a material having high thermal conductivity is desirable. Specifically, the first structure body 131 can be made of a metal material such as Au or Cu.

Further, since the interval between the first structure body 131 and the element part influences the area occupied by the final HBT and the parasitic capacitance, the optimum interval is set in a view of the process accuracy and the electrical characteristics.

In addition, the thickness (height) of the first structure body 131 is made equal to the sum of the thicknesses of the second emitter electrode 103, the emitter layer 104, the base layer 105, and the collector layer 106. Thus, as will be described later, the bonding pressure applied when bonding the growth substrate 121 and the heat dissipation substrate 101 is uniformly applied to the second emitter electrode 103 and the first structure body 131, and the deterioration of the crystal quality and the crack of the element part due to excessive pressure concentration can be suppressed.

Next, as shown in FIG. 2D, a first insulating layer 132 made of an insulating material having thermal conductivity higher than that of the collector layer 106 and the emitter layer 104 is formed on the peripheral surface (part of) of the element part (fifteenth step). In this example, the first insulating layer 132 is formed on the entire region including the element part on the collector contact forming layer 127.

As will be described later, the first insulating layer 132 serves to assist heat conduction of the element part and to protect the element part from an etchant when the first structure body 131 is etched to form a part of the heat dissipation structure. Therefore, it is desirable that the material of the first insulating layer 132 is made of a silicon nitride film (SiN) or alumina (Al₂O₃) having relatively high thermal conductivity and high chemical stability. The first insulating layer 132 made of these materials can be formed by, for example, chemical vapor deposition (CVD) or atomic layer deposition (ALD). Since the thickness of the first insulating layer 132 depends on the size and film quality of the element part, the thickness for obtaining the above-mentioned effect is appropriately set. Typically, the first insulating layer 132 has a thickness of about 10 nm to 100 nm, which is sufficient to obtain the above effect.

Next, as shown in FIG. 2E, the periphery of the element part is filled, and a first protective layer 133 is formed in which one end side of the first structure body 131 and the second emitter electrode 103 are exposed and a surface is flattened (fourth process).

For example, benzocyclobutene (BCB) is applied to the entire surface of the growth substrate 121 to form a coating film, and after the upper surface of the coating film is flattened, the coating film is etched back. In the etch-back process, the first insulating layer 132 on the second emitter electrode 103 and the first structure body 131 is removed together with a part of the coating film by a dry etching method. At this time, when the dry etching time is lengthened in order to surely expose the surface of the second emitter electrode 103, the height of a formation region of the first protective layer 133 on the element part becomes low, and there is a situation in which a region where the first protective layer 133 is formed is not bonded to the heat dissipation substrate 101.

Also in this state, the effect of embodiments of the present invention can be obtained. However, by using chemical mechanical polishing as a substitute for dry etching, for example, the surface of the second emitter electrode 103 and the surface of the first protective layer 133 are flattened so as to become in a state in which heights of the surface of the second emitter electrode 103 and the surface of the first protective layer 133 are aligned (the surface of the second emitter electrode 103 and the surface of the first protective layer 133 form the same plane), and the occurrence of the non-bonded region can be suppressed.

Next, as shown in FIG. 2F, a first adhesive metal layer 134 is formed on the flattened first protective layer 133 (fifth step). Further, as shown in FIG. 2G, a heat dissipation substrate 101 is prepared which is made of an insulating material having a thermal conductivity higher than that of InP and has a second adhesive metal layer 135 formed on the surface (sixth step). The heat dissipation substrate 101 can be made of, for example, a material having higher thermal conductivity and higher insulation than that of InP, such as high-resistance Si, SiC, AlN, and diamond. Since each adhesive metal layer is used as the heat dissipation structure and an electric wiring as described later, it is desirable to be made of a metal having a relatively easy bonding and a high thermal conductivity and a high electric conductivity.

For example, the first adhesive metal layer 134 and the second adhesive metal layer 135 can be made of Au or Cu. Further, in order to improve adhesion with a first protective layer 133 made of a resin such as BCB and to suppress thermal diffusion of Au and Cu to the element part, a layer made of Ti, Mo, Ni, W, or these compounds can be inserted between the first protective layer 133 and the first adhesive metal layer 134.

The thicknesses of the first adhesive metal layer 134 and the second adhesive metal layer 135 can be set in view of the easiness of processing and the electric resistance in forming the first emitter electrode 102, as will be described later. Typically, these thicknesses do not affect the processability and provide a sufficiently low electric resistance, provided as long as they are from 100 nm to 500 nm.

Next, as shown in FIG. 2H, the first adhesive metal layer 134 of the growth substrate 121 and the second adhesive metal layer 135 of the heat dissipation substrate 101 are brought into contact with each other so as to face each other to form an adhesive metal layer in which the first adhesive metal layer 134 and the second adhesive metal layer 135 are integrated, and the growth substrate 121 and the heat dissipation substrate 101 are laminated together (seventh step). For example, the above-mentioned laminating can be performed by surface-activated bonding, atomic diffusion bonding, or the like.

If the outermost surfaces of the first adhesive metal layer 134 and the second adhesive metal layer 135, which are the contact surfaces, are made of Au, they can be bonded at a temperature of 150° C. or lower in any bonding technique. This temperature does not affect the crystallinity of the element part. In bonding, a bonding pressure may be applied to correct warpage and global roughness of each substrate. This bonding pressure is dispersed not only in a region where the second emitter electrode 103 is formed but also in a region where the first structure body 131 is formed. Therefore, pressure is not locally concentrated on the second emitter electrode 103, and the risk of occurrence of deterioration of the crystal quality and cracks of the crystal layer constituting the element part immediately below the second emitter electrode 103 can be reduced.

Next, the growth substrate 121 and the etch stop layer 122 are removed, as shown in FIG. 2I, the element part is brought of being formed on the heat dissipation substrate 101 in a state where the second emitter electrode 103 is disposed in the heat dissipation substrate 101 side, and the collector contact forming layer 127 is exposed (eighth process).

The growth substrate 121 can be removed, for example, by known mechanical polishing. In addition, the removal of the growth substrate 121 can be performed, by utilizing well-known wet etching using a hydrochloric acid-based chemical. Further, the etch stop layer 122 may be removed by known wet etching. By using the etch stop layer 122, the growth substrate 121 can be reliably removed, and damage to the collector contact forming layer 127 can be avoided when the growth substrate 121 is removed.

Next, as shown in FIG. 2J, a collector electrode 108 is formed on the collector contact forming layer 127 (ninth process). The collector electrode 108 can be formed by known lithography, vacuum deposition method, or lift-off method.

The same number of collector electrodes 108 as the number of emitter layers 104 are formed in parallel so as to coincide with the central axis of each of the plurality of formed emitter layers 104. The width of each collector electrode 108 (length in the short side direction in a plan view) is wider than the width of each emitter layer 104, and each (adjacent) collector electrode 108 can be designed not to contact. In addition, the length of the collector electrode 108 (length in the long side direction in a plan view) can be designed at least within a range not reaching directly above the first structure body 131.

Next, as shown in FIG. 2K, a collector contact forming layer 127 is processed to form a collector contact layer 107. In addition, a part of the collector layer 106 and a part of the base layer 105 are removed to form a contact hole 116a reaching a part of the base electrode 109 (a part to be a base pad electrode) (tenth process).

For example, the collector contact forming layer 127 made of InGaAs can be etched using a citric acid-based etchant. By using this etching, the collector contact layer 107 can be formed. In addition, the base layer 105 made of GaAsSb can be etched using the citric acid-based etchant, and the collector layer 106 made of InP can be etched using a hydrochloric acid-based etchant. By using this etching, the contact hole 116a can be formed.

Further, the collector contact layer 107 and the collector layer 106 are additionally etched to divide the collector contact layer 107 and the collector layer 106 as shown in FIG. 2L. The width (length in the short side direction in a plan view) of each collector layer 106 and each collector contact layer 107 is designed to be wider than the width of each emitter layer 104. Similarly to the above, the collector contact layer 107 made of InGaAs can be etched by the citric acid-based etchant and the collector layer 106 made of InP can be etched by the hydrochloric acid-based etchant. Since the base layer 105 made of GaAsSb is not etched in the hydrochloric acid-based etchant, the collector layer 106 can be divided without removing the base layer 105.

Next, as shown in FIGS. 2M and 2N, a first emitter contact electrode 136 constituting a part of an emitter contact electrode 112 and a first heat dissipation structure 137 made of a metal and constituting a part of the heat dissipation structure 114 are formed on the first structure body 131, and a base contact electrode 116 is formed (eleventh step). Note that FIG. 2M shows a cross section in a direction parallel to the short side of the element part formed into a rectangular shape in a plan view, and FIG. 2N shows a cross section in a direction parallel to the long side of the element part formed into a rectangular shape in a plan view.

The first emitter contact electrode 136 is formed on the first structure body 131 on both sides of the element part in the short side direction in a plan view (FIG. 2M). The base contact electrode 116 is formed so as to fill the contact hole 116a and is formed in contact with the base electrode 109 (FIG. 2N). The first heat dissipation structure 137 is formed on the first structure body 131 on the side where the base contact electrode 116 is not formed (the left side in FIG. 2N) when viewed from the emitter layer 104 in the long side direction in a plan view. Any of these can be formed by using a known process similar to the formation of the collector electrode 108. The first emitter contact electrode 136 facilitates connection between the first emitter electrode 102 and the emitter wiring, and the base contact electrode 116 facilitates connection between the base electrode 109 and the base wiring.

Next, as shown in FIGS. 2O and 2P, the first structure body 131 is processed to form a second emitter contact electrode 138 connected to the first emitter contact electrode 136, and to form an emitter contact electrode 112. In addition, the first structure body 131 is processed to form a second heat dissipation structure 139 constituting a part of the heat dissipation structure 114 and connected to the first heat dissipation structure 137. In addition, the adhesive metal layer is processed to form a first emitter electrode 102, a third heat dissipation structure 140 connected to the second heat dissipation structure 139, and a heat dissipation structure 114 constituted by the first heat dissipation structure 137, the second heat dissipation structure 139, and the third heat dissipation structure 140 (twelfth step).

In the formation of the first emitter electrode 102 and the third heat dissipation structure 140, the adhesive metal layer outside the element forming region is completely removed. In addition, in the formation of the second emitter contact electrode 138 and the second heat dissipation structure 139, the first structure body 131 outside the element forming region is completely removed. Note that FIG. 2O shows a cross section in a direction parallel to a short side of the element part formed into a rectangular shape in a plan view, and FIG. 2P shows a cross section in a direction parallel to a long side of the element part formed into a rectangular shape in a plan view.

For example, a region where the second emitter contact electrode 138, the second heat dissipation structure 139, and the first emitter electrode 102 is formed, and a top of the base contact electrode 116 are covered with a resist mask, and in this state, the first structure body 131 and the adhesive metal layer are wet-etched using an appropriate etchant, thereby forming each portion. When the adhesive metal layer and the first structure body 131 are made of Au, wet etching can be performed by using an iodine-based etchant, for example. In this etching, the first insulating layer 132 prevents an etchant from contacting the element part, and can prevent unintended etching from occurring in the element part.

Next, as shown in FIGS. 2Q and 2R, a second insulating layer 141 made of an insulating material having a thermal conductivity higher than that of the collector layer 106 and the emitter layer 104 is formed on a part of the peripheral surface of the element part (sixteenth process). Note that FIG. 2Q shows a cross section in a direction parallel to the short side of the element part formed into a rectangular shape in a plan view, and FIG. 2R shows a cross section in a direction parallel to the long side of the element part formed into a rectangular shape in a plan view. The second insulating layer 141 can improve the heat dissipation property from the collector layer 106 to the collector electrode 108 by using a material such as SiN or Al₂O₃ having thermal conductivity higher than that of a compound semiconductor constituting the element part.

Next, as shown in FIGS. 2S and 2T, a second protective layer 142 is formed on the first protective layer 133 to form a protective layer 11o constituted by the first protective layer 133 and the second protective layer 142 (thirteenth process). Note that FIG. 2S shows a cross section in a direction parallel to the short side of the element part formed into a rectangular shape in a plan view, and FIG. 2T shows a cross section in a direction parallel to the long side of the element part formed into a rectangular shape in a plan view.

For example, BCB is applied to the entire surface to form a coating film, and after the upper surface of the coating film is flattened, the coating film is etched back. In etch-back, the dry etching method is used, and the collector electrode 108, the emitter contact electrode 112, the base contact electrode 116, and the second insulating layer 141 on the heat dissipation structure 114 are removed together with a part of the coating film, and the second protective layer 142 is formed in a state where the upper surface of each part is exposed.

Thereafter, an emitter wiring 113, a base wiring 117, and a collector wiring 115 are formed (fourteenth step), whereby the hetero-junction bipolar transistor according to the embodiment is obtained.

In the above-described manufacturing method, an example in which laminating of the growth substrate 121 and the heat dissipation substrate 101 is carried out by bonding via an adhesive metal layer is shown, but the embodiments of the present invention are not limited to this, the same structure can be formed without impairing the effect of embodiments of the present invention by another laminating technique (bonding technique).

For example, after the element part is formed as described with reference to FIGS. 2B and 2C, the first emitter contact electrode, the first heat dissipation structure, the second emitter contact electrode, and the second heat dissipation structure are formed as described with reference to FIGS. 2M, 2N, 2O, and 2P, these are filled with a resin film, the resin film is etched back, and the surface of the second emitter contact electrode and the second heat dissipation structure is exposed. On the other hand, the first emitter electrode and the third heat dissipation structure are formed on the heat dissipation substrate, and are flattened by forming the resin film and etch back by CMP in this case. Finally, the growth substrate and the heat dissipation substrate are laminated by hybrid bonding via the portions of the respective resin films and the metal portions while alignment is performed so that the positional relationship between the second emitter contact electrode and the first emitter electrode, the positional relationship between the second heat dissipation structure and the third heat dissipation structure, and the like are matched, and the growth substrate is removed.

Also, by this method, since both substrates are bonded with their surfaces flattened, local application of bonding pressure to the second emitter electrode can be prevented, and deterioration of crystallinity of the element part can be suppressed.

Note that although an npn-type InP/GaAsSb-based HBT on a heat dissipation substrate that is promising in terms of realizing a very high-speed integrated circuit is described in detail in the above, a similar effect is also valid for other HBTs.

As described above, according to embodiments of the present invention, since the protective layer covering the element part or the like is formed on the heat dissipation substrate, and the heat dissipation structure is provided which is made of metal and has one end in contact with the top of the heat dissipation substrate around the element part and formed through the protective layer, it is possible to suppress the deterioration of crystal quality and the deterioration of integration density of the InP-based HBT to improve the heat dissipation property.

Note that it is clear that the embodiments of the present invention are not limited to the embodiments described above and within the technical concept of the present invention, many modifications and combinations can be implemented by those skilled in the art.

1.-6. (canceled)

7. A hetero-junction bipolar transistor comprising:
a heat dissipation substrate comprising an insulating material having a thermal conductivity higher than that of InP;
a first emitter electrode on the heat dissipation substrate;
a second emitter electrode on the first emitter electrode and having an area smaller than that of the first emitter electrode;
an emitter layer comprising a first compound semiconductor on the second emitter electrode;
a base layer comprising a second compound semiconductor on the emitter layer;
a collector layer comprising a third compound semiconductor on the base layer;
a collector contact layer comprising a fourth compound semiconductor on the collector layer;
a collector electrode on the collector contact layer;
a base electrode configured to be connected to the base layer;
a protective layer on the heat dissipation substrate covering a side of an element part, the first emitter electrode, and the base electrode the element part comprising the second emitter electrode, the emitter layer, the base layer, the collector layer, the collector contact layer;
an emitter contact electrode in contact with a top of the first emitter electrode around the element part and penetrating the protective layer;
an emitter wiring on the protective layer and connected to the emitter contact electrode;
a heat dissipation structure comprising a metal and having one end in contact with a top of the heat dissipation substrate around the element part and extending through the protective layer;
a collector wiring on the protective layer in contact with the top of the heat dissipation substrate and the collector electrode;
a base contact electrode connected to the base electrode and penetrating the protective layer; and
a base wiring on the protective layer and connected to the base contact electrode.

8. The hetero-junction bipolar transistor according to claim 7, further comprising an insulating layer on a peripheral surface of the element part, the insulating layer comprising a second insulating material having a thermal conductivity higher than that of the collector layer and the emitter layer.

9. The hetero-junction bipolar transistor according to claim 8, further comprising a plurality of the element parts on the first emitter electrode, wherein each of the element parts has a rectangular shape in a plan view and is disposed in a direction of a short side of the rectangular shape, and wherein, in the plurality of the element parts, the collector layer has an area larger than that of the emitter layer.

10. The hetero-junction bipolar transistor according to claim 7, further comprising a plurality of the element parts on the first emitter electrode, wherein each of the element parts has a rectangular shape in a plan view and is disposed in a direction of a short side of the rectangular shape, and wherein, in the plurality of the element parts, the collector layer has an area larger than that of the emitter layer.

11. A manufacturing method for manufacturing a hetero-junction bipolar transistor, the method comprising:
performing crystal growth of an etch stop layer, a collector contact forming layer, a collector forming layer, a base forming layer, and an emitter forming layer in this order, wherein each of the etch stop layer, the collector contact forming layer, the collector forming layer, the base forming layer, and the emitter forming layer comprise a compound semiconductor on a growth substrate comprising InP;
forming an element part by forming a second emitter electrode on the emitter forming layer, processing the emitter forming layer, the base forming layer, and the collector forming layer to form an emitter layer, a base layer, and a collector layer, and forming a base electrode on the base layer around the emitter layer;
forming a first structure body comprising a first metal on the growth substrate around the element part;
filling a periphery of the element part and forming a first protective layer in which one end side of the first structure body and the second emitter electrode are exposed and a surface is flattened;
forming a first adhesive metal layer on the flattened surface of the first protective layer;
preparing a heat dissipation substrate comprising an insulating material having higher thermal conductivity than that of InP and in which a second adhesive metal layer is formed on the surface;
bringing the first adhesive metal layer of the growth substrate and the second adhesive metal layer of the heat dissipation substrate into contact with each other so as to face each other, forming an adhesive metal layer in which the first adhesive metal layer and the second adhesive metal layer are integrated, and laminating the growth substrate and the heat dissipation substrate;
removing the growth substrate and the etch stop layer, bringing the element part into a state of being formed on the heat dissipation substrate in a state where the second emitter electrode is disposed on a side of the heat dissipation substrate, and exposing the collector contact forming layer;
forming a collector electrode on the collector contact forming layer;
forming a collector contact layer by processing the collector contact forming layer and further removing a part of the collector layer and the base layer and forming a contact hole reaching a part of the base electrode;
forming a first emitter contact electrode comprising a part of an emitter contact electrode and a first heat dissipation structure comprising a second metal and comprising a part of a heat dissipation structure and forming a base contact electrode on the first structure body;
forming an emitter contact layer by processing the first structure body and forming a second emitter contact electrode connecting to the first emitter contact electrode, forming a second heat dissipation structure comprising a part of the heat dissipation structure and connected to the first heat dissipation structure, forming a first emitter electrode by processing the adhesive metal layer, and forming a third heat dissipation structure connected to the second heat dissipation structure to form the heat dissipation structure comprising the first heat dissipation structure, the second heat dissipation structure, and the third heat dissipation structure;
forming a second protective layer on the first protective layer to form a protective layer comprising the first protective layer and the second protective layer; and
forming an emitter wiring, a base wiring, and a collector wiring.

12. The method according to claim 11, further comprising:
before filling the periphery of the element part and forming the first protective layer and after forming the first structure body, forming a first insulating layer comprising a first insulating material having a thermal conductivity higher than that of the collector layer and the emitter layer in a first part of a peripheral surface of the element part; and
before forming the second protective layer and after forming the emitter contact layer, the second heat dissipation structure, the first emitter electrode, and the third heat dissipation structure connected to the second heat dissipation structure to form the heat dissipation structure, forming a second insulating layer comprising a second insulating material having a thermal conductivity higher than that of the collector layer and the emitter layer in a second part of the peripheral surface of the element part.

13. The method according to claim 12, wherein forming the element part comprises forming a plurality of the element parts, and wherein forming the collector electrode comprises forming the collector electrode individually for each of the plurality of the element parts.

14. The method according to claim 13, wherein each of the element parts has a rectangular shape in a plan view and is disposed in a direction of a short side of the rectangular shape, and wherein, in the plurality of the element parts, the collector layer has an area larger than that of the emitter layer.

15. The method according to claim 11, wherein forming the element part comprises forming a plurality of the element parts, and wherein forming the collector electrode comprises forming the collector electrode individually for each of the plurality of the element parts.

16. The method according to claim 15, wherein each of the element parts has a rectangular shape in a plan view and is disposed in a direction of a short side of the rectangular shape, and wherein, in the plurality of the element parts, the collector layer has an area larger than that of the emitter layer.
